(19) United States
(12) Patent Application Publication
(10) Pub. No.: US 2023/0187334 A1
(43) Pub. Date: Jun. 15, 2023

(54) SEMICONDUCTOR DEVICE

(71) Applicant: FUJI ELECTRIC CO., LTD., Kawasaki-shi (JP)

(72) Inventors: Yuma MURATA, Matsumoto-city (JP); Katsumi TANIGUCHI, Matsumoto-city (JP); Ryoichi KATO, Matsumoto-city (JP)

(73) Assignee: FUJI ELECTRIC CO., LTD., Kawasaki-shi (JP)

(21) Appl. No.: 17/974,814

(22) Filed: Oct. 27, 2022

(30) Foreign Application Priority Data
Dec. 14, 2021 (JP) 2021-202684

(51) Int. Cl. H01L 23/498

(52) U.S. Cl. CPC H01L 23/49844; H01L 23/49861; H01L 23/49811; H01L 2224/48225; H01L 2924/13091; H01L 24/48

(57) ABSTRACT

A semiconductor device includes: an insulating sheet including a first main surface and a second main surface; a first terminal in a shape of a plate provided to face the first main surface of the insulating sheet and including a first protruding portion protruding outward from the first main surface of the insulating sheet; and a second terminal in a shape of a plate provided to face the second main surface of the insulating sheet and including a second protruding portion protruding outward from the second main surface of the insulating sheet side by side with the first protruding portion, wherein a first recessed portion is provided at a position of the first protruding portion intersecting an end portion of the insulating sheet by concaving a side surface of the first protruding portion facing the second protruding portion in a direction away from the second protruding portion.

### CROSS-REFERENCE TO RELATED APPLICATION

This application claims benefit of priority under 35 USC 119 based on Japanese Patent Application No. 2021-202684 filed on Dec. 14, 2021, the entire contents of which are incorporated by reference herein.

### BACKGROUND OF THE INVENTION

### 1. Field of the Invention

The present invention relates to semiconductor devices (power semiconductor modules) including power semiconductor elements.

### 2. Description of the Related Art

In recent years, electric vehicles such as electric cars and electric railway vehicles have been attracting attention due to a global trend toward decarbonization. Electric vehicles require efficient motor control using a power conversion system such as an inverter or a converter, in which the power conversion system generally uses a power semiconductor module. A power semiconductor module coverts DC power to AC power, or vice versa. A power semiconductor module includes a plurality of power semiconductor elements (switching elements), such as insulated gate bipolar transistors (IGBTs), metal oxide semiconductor field effect transistors (MOSFETs), and diodes. Power conversion is performed by switching these power semiconductor elements on and off.

Switching a power semiconductor element on and off causes a switching loss. Although the switching loss can be reduced by switching as fast as possible, fast switching may cause overvoltage. The occurrence of overvoltage not only leads to increased loss, but also may damage the power semiconductor module. Reducing parasitic inductance of wiring, which is a so-called “inductance reduction”, is known to be effective in suppressing overvoltage during fast switching. In a 2-in-1 module including power semiconductor elements such as IGBTs or MOSFETs connected in series, a positive electrode terminal and a negative electrode terminal connected to ends of the series connection, and an AC output terminal connected between the power semiconductor elements, inductance reduction can be achieved by using a so-called laminated wiring structure in which the positive and negative electrode terminals are stacked via an insulating sheet so that currents flow in opposite directions.

JP 2021-106235 A discloses a semiconductor device including a terminal laminated portion in which a first power terminal, a first insulating sheet, and a second power terminal are stacked in order. The first power terminal has a first bonding region conductively connected to a first connection terminal of a capacitor. The second power terminal has a second bonding region conductively connected to a second connection terminal of the capacitor. The first insulating sheet has a terrace portion extending in a direction from the second bonding region to the first bonding region in plan view.

### SUMMARY OF THE INVENTION

In the power semiconductor module having the laminated wiring structure, the positive and negative electrode terminals protrude further inward than an end portion of the insulating sheet inside a case housing the power semiconductor elements, and the protruding portions are electrically connected to the power semiconductor elements. The positive and negative electrode terminals are sealed by resin filled inside the case.

However, when the resin sealing the positive and negative electrode terminals is peeled off, a creepage distance between the positive and negative electrode terminals may become insufficient.

In view of the above problem, it is an object of the present invention to provide a semiconductor device that, in a laminated wiring structure in which a positive electrode terminal and a negative electrode terminal are stacked via an insulating sheet, can secure a creepage distance between the positive and negative electrode terminals, enabling improved insulating performance.

An aspect of the present invention inheres in a semiconductor device including: an insulating sheet including a first main surface and a second main surface; a first terminal in a shape of a plate provided to face the first main surface of the insulating sheet and including a first protruding portion protruding outward from the first main surface of the insulating sheet; and a second terminal in a shape of a plate provided to face the second main surface of the insulating sheet and including a second protruding portion protruding outward from the second main surface of the insulating sheet side by side with the first protruding portion, wherein a first recessed portion is provided at a position of the first protruding portion intersecting an end portion of the insulating sheet by concaving a side surface of the first protruding portion facing the second protruding portion in a direction away from the second protruding portion.

### BRIEF DESCRIPTION OF THE DRAWINGS

FIG. 1 is a plan view of a semiconductor device according to a first embodiment;

FIG. 2 is a plan view of a positive electrode terminal of the semiconductor device according to the first embodiment;

FIG. 3 is a plan view of a negative electrode terminal of the semiconductor device according to the first embodiment;

FIG. 4 is a sectional view as seen from an A-A direction of FIG. 1;

FIG. 5 is a sectional view as seen from a B-B direction of FIG. 1;

FIG. 6 is a sectional view as seen from a C-C direction of FIG. 1;

FIG. 7 is a circuit diagram of the semiconductor device according to the first embodiment;

FIG. 8 is a plan view of a semiconductor device according to a comparative example;

FIG. 9 is a sectional view as seen from a C-C direction of FIG. 8;

FIG. 10 is a plan view of a semiconductor device according to a second embodiment;

FIG. 11 is a sectional view as seen from an A-A direction of FIG. 10;

FIG. 12 is a sectional view as seen from a B-B direction of FIG. 10;

FIG. 13 is a sectional view as seen from a C-C direction of FIG. 10;

FIG. 14 is a sectional view of a semiconductor device according to a third embodiment;

FIG. 15 is another sectional view of the semiconductor device according to the third embodiment;

FIG. 16 is a plan view of a semiconductor device according to a fourth embodiment;

FIG. 17 is a sectional view as seen from an A-A direction of FIG. 16;

FIG. 18 is a sectional view as seen from a B-B direction of FIG. 16;

FIG. 19 is a plan view of a semiconductor device according to a fifth embodiment;

FIG. 20 is a sectional view as seen from an A-A direction of FIG. 19; and

FIG. 21 is a sectional view as seen from a B-B direction of FIG. 19.

### DETAILED DESCRIPTION

With reference to the Drawings, first to fifth embodiments of the present invention will be described below.

In the Drawings, the same or similar elements are indicated by the same or similar reference numerals. The Drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

Additionally, definitions of directions such as “upper”, “lower”, “upper and lower”, “left”, “right”, and “left and right” in the following description are simply definitions for convenience of description, and do not limit the technological concept of the present invention. For example, when observing an object rotated by 90 □, the “upper and lower” are converted to “left and right” to be read, and when observing an object rotated by 180 □, the “upper and lower” are read reversed, which should go without saying. In addition, an “upper surface” and a “lower surface”, respectively, may be read as “front surface” and “back surface”.

Additionally, in the present specification, a “first terminal” refers to any one of a positive electrode terminal and a negative electrode terminal of a power semiconductor module, and a “second terminal” refers to the other one different from the “first terminal” of the positive and negative electrode terminals of the power semiconductor module. In other words, when the “first terminal” is the positive electrode terminal of the power semiconductor module, the “second terminal” is the negative electrode terminal of the power semiconductor module, whereas when the “first terminal” is the negative electrode terminal of the power semiconductor module, the “second terminal” is the positive electrode terminal of the power semiconductor module. In addition, a “first main surface” and a “second main surface” of each member are main surfaces facing each other, and for example, when the “first main surface” is an upper surface, the “second main surface” is a lower surface.

### First Embodiment

<Structure of Semiconductor Device>

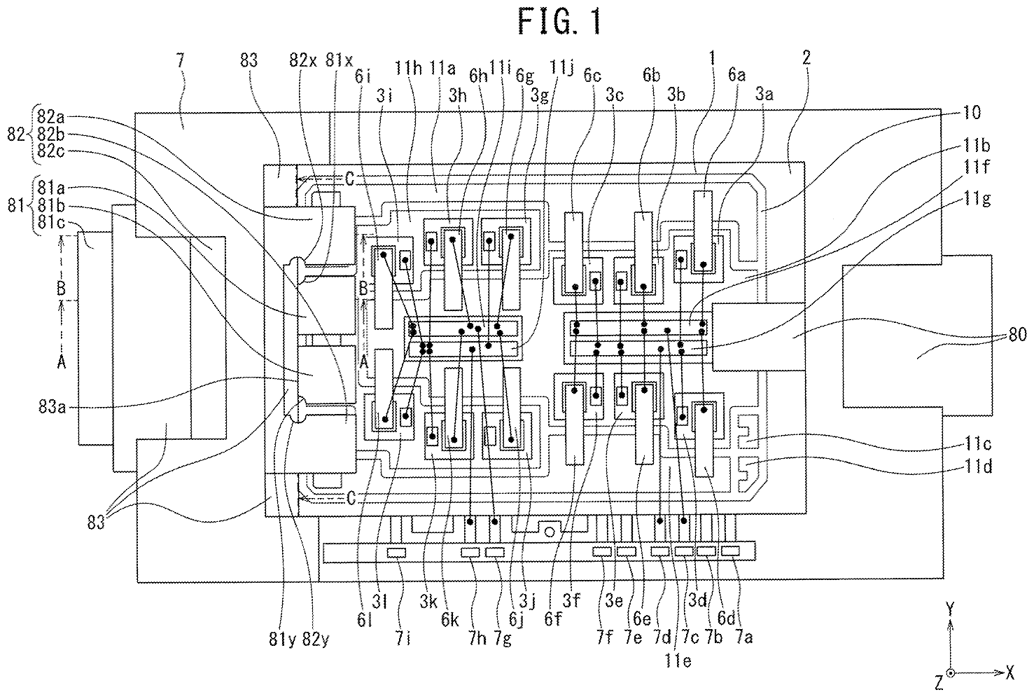

A semiconductor device (power semiconductor module) according to a first embodiment includes an insulated circuit substrate 1, power semiconductor elements (semiconductor chips) 3a to 3l mounted on the insulated circuit substrate 1, and a case 7 arranged so as to surround the insulated circuit substrate 1 and the power semiconductor elements 3a to 3l, as illustrated in FIG. 1. In FIG. 1, illustration of a sealing material arranged inside the case 7 and sealing the power semiconductor elements 3a to 3l and the like is omitted. FIG. 1 also schematically illustrates connection points of bonding wires connected to the power semiconductor elements 3a to 3l and the like by using black circles.

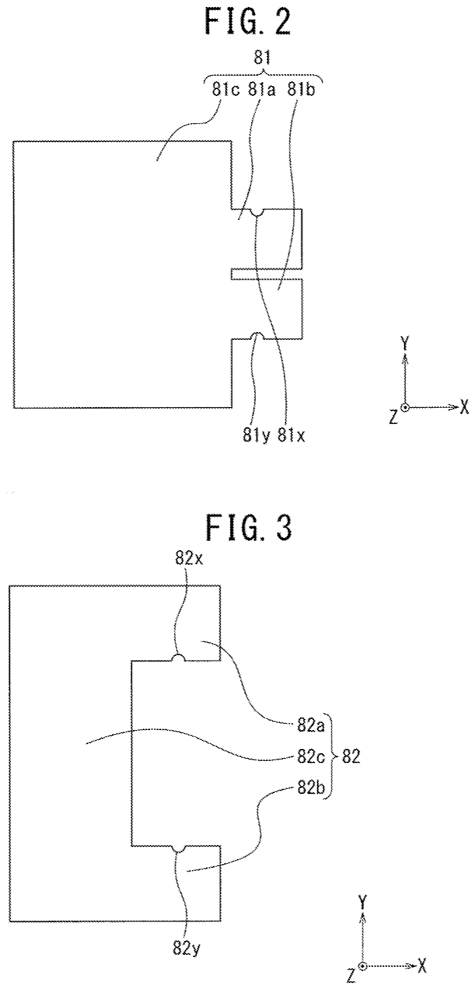

In a plan view illustrated in FIG. 1, a longitudinal direction of the semiconductor device according to the first embodiment is defined as X axis, and a right direction of FIG. 1 is defined as a positive direction of the X axis. Additionally, a traverse direction of the semiconductor device according to the first embodiment orthogonal to the X axis is defined as Y axis, and an upper direction of FIG. 1 is defined as a positive direction of the Y axis. In addition, a direction orthogonal to the X axis and the Y axis is defined as Z axis, and a front side of FIG. 1 is defined as a positive direction of the Z axis. The same applies even to FIG. 2 and thereafter.

FIG. 1 exemplifies a 2-in-1 type power semiconductor module in which as the power semiconductor elements 3a to 3l, two pairs of six-parallel MOSFETS are connected in series. Power semiconductor elements 3a to 3f constitutes upper arms of one phase of a three-phase inverter circuit, and power semiconductor elements 3g to 3l constitute lower arms thereof. Note that the semiconductor device according to the first embodiment can be any power semiconductor module that includes a positive electrode terminal 81 and a negative electrode terminal 82. The semiconductor device according to the first embodiment is not limited to a 2-in-1 type semiconductor module, and for example, may be a 1-in-1 type or 6-in-1 type semiconductor module.

The power semiconductor elements 3a to 3l include a semiconductor substrate, a first main electrode (drain electrode) provided on a lower surface side of the semiconductor substrate, and a second main electrode (source electrode) and a control electrode (gate electrode) provided on an upper surface side of the semiconductor substrate. The semiconductor substrate is composed of, for example, silicon (Si), silicon carbide (SiC), gallium nitride (GaN), gallium oxide (Ga₂O₃), or the like. The arrangement positions and number of the power semiconductor elements 3a to 3l are not particularly limited. The power semiconductor elements 3a to 3l may be insulated gate bipolar transistors (IGBTs), static induction (SI) thyristors, gate turn-off (GTO) thyristors, or the like, other than field effect transistors (FETs) such as MOSFETs.

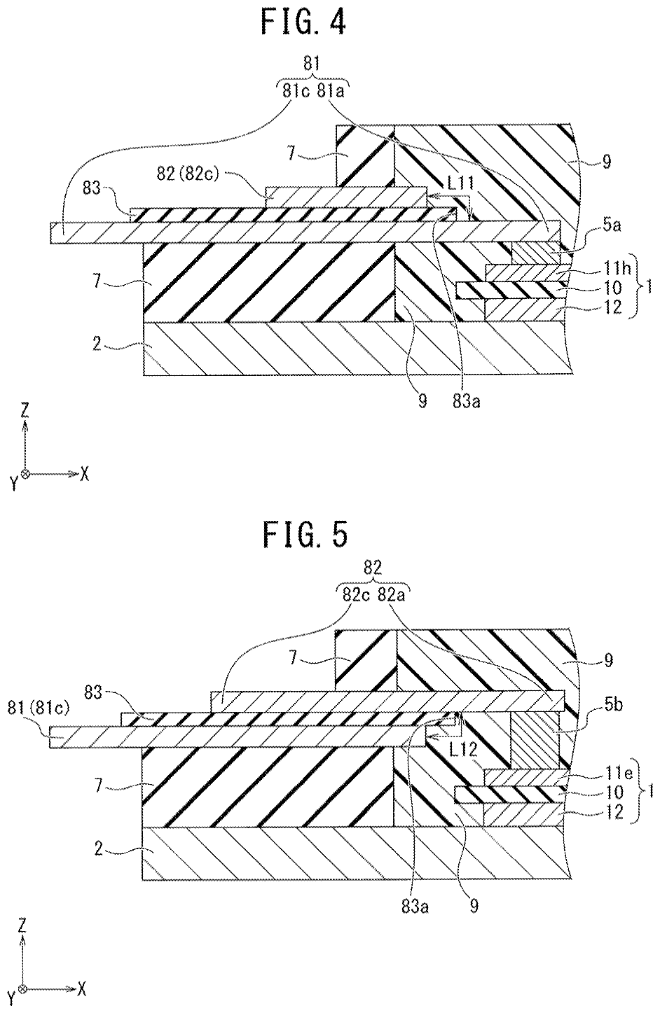

The insulated circuit substrate 1 is composed of, for example, a direct copper bonded (DCB) substrate, an active metal brazed (AMD) substrate, or the like. The insulated circuit substrate 1 includes an insulating substrate 10, conductive foils (upper conductive foils) 11a to 11j arranged on an upper surface of the insulating substrate 10, and a conductive foil (lower conductive foil) 12 arranged on a lower surface of the insulating substrate 10 (see FIG. 4 and FIG. 5 for the lower conductive foil 12). Examples of the insulating substrate 10 that can be used include a ceramic substrate made mainly of aluminum oxide (Al₂O₃), aluminum nitride (AlN), silicon nitride (Si₃N₄), boron nitride (BN), or the like and a resin insulation layer made of a polymer material or the like. When a resin insulation layer is used as the insulating substrate 10, the lower conductive foil 12 on the lower surface side of the insulating substrate 10 is not required. The upper conductive foils 11a to 11j and the lower conductive foil 12 are composed of, for example, copper (Cu), aluminum (Al), or the like. The upper conductive foils 11a to 11j are formed in any pattern, and constitute circuit patterns.

As illustrated in FIG. 1, the power semiconductor elements 3a to 3f are bonded onto an upper conductive foil 11b of the insulated circuit substrate 1 via solder, sintered material, or other bonding material. The power semiconductor elements 3g to 3l are bonded onto an upper conductive foil 11h of the insulated circuit substrate 1 via solder, sintered material, or other bonding material.

The case 7 is arranged so as to surround the power semiconductor elements 3a to 3f and the insulated circuit substrate 1. The material of the case 7 that can be used is a resin material such as polyphenylene sulfide (PPS), polybutylene terephthalate (PBT), polybutylene succinate (PBS), epoxy, or phenol.

The case 7 is provided with control terminals 7a to 7i. A control terminal 7c is connected to an upper conductive foil 11f via a bonding wire. The upper conductive foil 11f is electrically connected to the source electrode of each of the power semiconductor elements 3a to 3f via a bonding wire. The control terminal 7c detects current that flows through the source electrodes of the power semiconductor elements 3a to 3f.

A control terminal 7d is connected to an upper conductive foil 11g via a bonding wire. The upper conductive foil 11g is electrically connected to the gate electrode of each of the power semiconductor elements 3a to 3f via a bonding wire. The control terminal 7d applies a control signal to the gate electrode of each of the power semiconductor elements 3a to 3f.

A control terminal 7g is connected to an upper conductive foil 11i via a bonding wire. The upper conductive foil 11i is electrically connected to the source electrode of each of the power semiconductor elements 3g to 3l via a bonding wire. The control terminal 7g detects current that flows through the source electrodes of the power semiconductor elements 3g to 3l.

A control terminal 7h is connected to an upper conductive foil 11j via a bonding wire. The upper conductive foil 11j is electrically connected to the gate electrode of each of the power semiconductor elements 3g to 3l via a bonding wire. A control signal is applied to the gate electrode of each of the power semiconductor elements 3g to 3l via the control terminal 7h.

The case 7 is provided with an output terminal 80 in a shape of a plate and the positive and negative electrode terminals 81 and 82 each in a shape of a plate arranged so as to face the output terminal 80. The output terminal 80 is connected to the upper conductive foil 11b. The upper conductive foil 11b is electrically connected to the drain electrode of each of the power semiconductor elements 3a to 3f The upper conductive foil 11b is also electrically connected to the source electrode of each of the power semiconductor elements 3g to 3l via lead frames 6g to 6l.

The positive electrode terminal 81 and the negative electrode terminal 82 are used as terminals with different potentials from each other. The positive electrode terminal 81 is electrically connected to the upper conductive foil 11h. The upper conductive foil 11h is electrically connected to the drain electrode of each of the power semiconductor elements 3g to 3l. The negative electrode terminal 82 is electrically connected to the upper conductive foils 11a and 11e. The upper conductive foil 11a is electrically connected to the source electrode of each of the power semiconductor elements 3a to 3c via lead frames 6a to 6c. The upper conductive foil 11e is electrically connected to the source electrode of each of the power semiconductor elements 3d to 3f via lead frames 6d to 6f.

FIG. 2 illustrates a planar pattern of the positive electrode terminal 81. As illustrated in FIG. 2, the positive electrode terminal 81 includes protruding portions 81a and 81b spaced from each other and extending in parallel to each other on the planar pattern and a main body portion 81c connected to the protruding portions 81a and 81b. A recessed portion (notched portion) 81x is provided on a side surface of the protruding portion 81a opposite to a side thereof facing the protruding portion 81b in a direction (traverse direction) orthogonal to an extending direction of the protruding portion 81a. A recessed portion (notched portion) 81y is provided on a side surface of the protruding portion 81b opposite to a side thereof facing the protruding portion 81a in the direction (traverse direction) orthogonal to the extending direction of the protruding portion 81b. The recessed portions 81x and 81y have a semicircular planar pattern. Note that the planar pattern shape of the recessed portions 81x and 81y is not particularly limited, and may be, for example, a planar pattern shape of a polygon such as a rectangle.

As illustrated in FIG. 1, the protruding portions 81a and 81b protrude and extend outward from an insulating sheet 83 inside the case 7, and are electrically connected to the upper conductive foil 11h. The recessed portion 81x of the protruding portion 81a is provided at a position of the protruding portion 81a intersecting an end portion 83a of the insulating sheet 83 so as to concave the side surface of the protruding portion 81a facing the protruding portion 82a in a direction away from the protruding portion 82a. The recessed portion 81y of the protruding portion 81b is provided at a position of the protruding portion 81b intersecting the end portion 83a of the insulating sheet 83 so as to concave the side surface of the protruding portion 81b facing the protruding portion 82b in a direction away from the protruding portion 82b.

FIG. 3 illustrates a planar pattern of the negative electrode terminal 82. As illustrated in FIG. 3, the negative electrode terminal 82 includes protruding portions 82a and 82b spaced from each other and extending in parallel to each other on the planar pattern and a main body portion 82c connected to the protruding portions 82a and 82b. A recessed portion (notched portion) 82x is provided on a side surface of the protruding portion 82a on a side facing the protruding portion 82b in a direction (traverse direction) orthogonal to an extending direction of the protruding portion 82a. A recessed portion (notched portion) 82y is provided on a side surface of the protruding portion 82b on a side facing the protruding portion 82a in the direction (traverse direction) orthogonal to the extending direction of the protruding portion 82b. The recessed portions 82x and 82y have a semicircular planar pattern. Note that the planar pattern shape of the recessed portions 82x and 82y is not particularly limited, and may be, for example, a planar pattern shape of a polygon such as a rectangle. The planar pattern shape of the recessed portions 82x and 82y may be the same as or different from that of the recessed portions 81x and 81y.

As illustrated in FIG. 1, the protruding portions 82a and 82b protrude and extend outward from the insulating sheet 83 inside the case 7, and are electrically connected to the upper conductive foils 11a and 11e. The recessed portion 82x of the protruding portion 82a is provided at a position of the protruding portion 82a intersecting the end portion 83a of the insulating sheet 83 so as to concave the side surface facing the protruding portion 81a in a direction away from the protruding portion 81a. The recessed portion 82y of the protruding portion 82b is provided at a position of the protruding portion 82b intersecting the end portion 83a of the insulating sheet 83 so as to concave the side surface facing the protruding portion 81b in a direction away from the protruding portion 81b.

The insulating sheet 83 has a planar pattern shape corresponding to the planar pattern shapes of the positive and negative electrode terminals 81 and 82. In order to secure a required insulation creepage distance between the positive electrode terminal 81 and the negative electrode terminal 82, outer edges (end portions) of the insulating sheet 83 are larger in size than outer edges (end portions) of the positive and negative electrode terminals 81 and 82.

FIG. 4 illustrates a section as seen from an A-A direction passing through the protruding portion 81a of the positive electrode terminal 81 of FIG. 1. As illustrated in FIG. 4, the insulated circuit substrate 1, the power semiconductor elements 3a to 3l, and the like inside the case 7 are sealed by a sealing material 9. An insulating sealing resin such as thermosetting silicone gel or epoxy-based resin can be used as the sealing material 9. On a lower surface side of the insulated circuit substrate 1 is arranged a cooling body (base) 2. Examples of the material of the cooling body 2 that can be used include materials having high thermal conductivity, such as copper (Cu), aluminum (Al), a composite material (AlSiC) consisting of aluminum (Al) and silicon carbide (SiC), and a composite material (MgSiC) consisting of magnesium (Mg) and silicon carbide (SiC).

As illustrated in FIG. 4, the insulating sheet 83 is arranged between an upper surface of the positive electrode terminal 81 and a lower surface of the negative electrode terminal 82. In other words, the positive and negative electrode terminals 81 and 82 constitute a laminated wiring structure in which the positive and negative electrode terminals 81 and 82 are stacked via the insulating sheet 83 from an inside of the power semiconductor module to an outside thereof. At least a part of the main body portion 81c of the positive electrode terminal 81 and at least a part of the main body portion 82c of the negative electrode terminal 82 face each other via the insulating sheet 83. A distance where the positive and negative electrode terminals 81 and 82 face each other is constant with a thickness of the insulating sheet 83. Current flows through the positive electrode terminal 81 and the negative electrode terminal 82 in opposite directions, thus enabling reduced parasitic inductance of the wiring.

A material of the positive and negative electrode terminals 81 and 82 that can be used is copper (Cu), Cu-alloy, aluminum (Al), Al-alloy, or the like. The positive electrode terminal 81 is electrically connected to the upper conductive foil 11h via a conductive block (spacer) 5a made of copper (Cu) material or the like for height adjustment. The protruding portion 81a of the positive electrode terminal 81 and the main body portion 82c of the negative electrode terminal 82 are separated by a creepage distance L11. The creepage distance L11 is a total value of a distance from an end portion of the main body portion 82c to the end portion 83a of the insulating sheet 83 and the thickness of the insulating sheet 83.

As the insulating sheet 83, insulating paper, or a highly insulative and heat-resistant sheet such as a polyimide or polyamide sheet can be used. The thickness of the insulating sheet 83 depends on rated voltage of the power semiconductor module. When the rated voltage is 1200 V, the thickness thereof is set from 0.1 mm to 1.0 mm. More preferably, setting the thickness to from 0.2 mm to 0.6 mm allows wiring inductances of the positive and negative electrode terminals 81 and 82 to be significantly reduced.

FIG. 5 illustrates a section as seen from a B-B direction passing through the protruding portion 82a of the negative electrode terminal 82 of FIG. 1. As illustrated in FIG. 5, the negative electrode terminal 82 is electrically connected to the upper conductive foil 11e via a conductive block (spacer) 5b made of copper (Cu) material or the like for height adjustment. A distance between the negative electrode terminal 82 and the insulated circuit substrate 1 is larger than a distance between the positive electrode terminal 81 and the insulated circuit substrate 1. Therefore, a height of the spacer 5b connected to the negative electrode terminal 82 is higher than a height of the spacer 5a connected to the positive electrode terminal 81. The main body portion 81c of the positive electrode terminal 81 and the protruding portion 82a of the negative electrode terminal 82 are separated by a creepage distance L12. The creepage distance L12 is a total value of a distance from an end portion of the main body portion 81c to the end portion 83a of the insulating sheet 83 and the thickness of the insulating sheet 83.

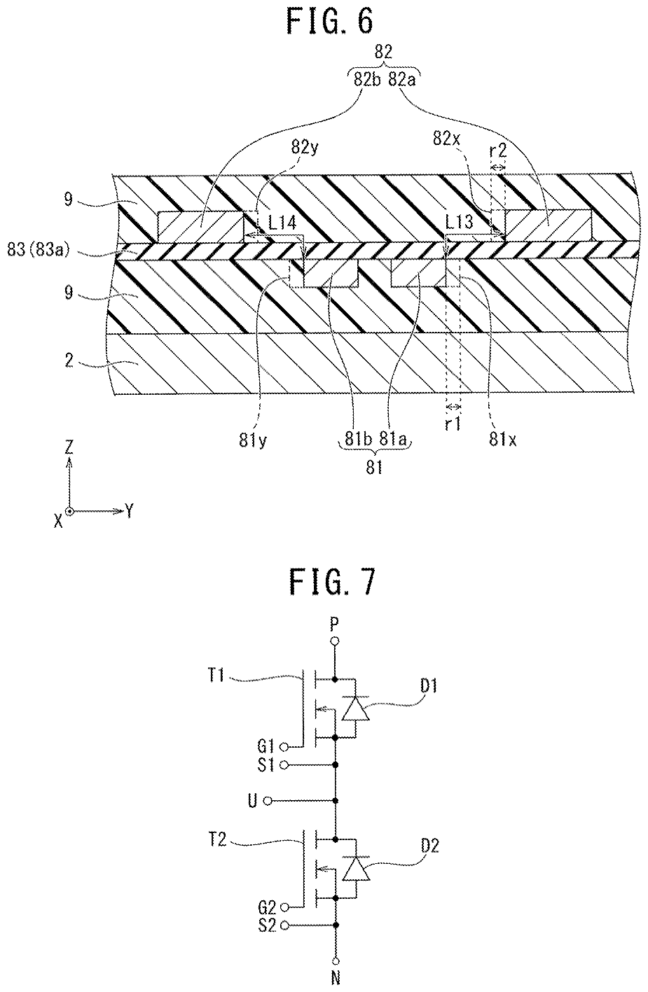

FIG. 6 illustrates a section as seen from a C-C direction passing through the recessed portion 81x of the protruding portion 81a of FIG. 1, the recessed portion 81y of the protruding portion 81b, the recessed portion 82x of the protruding portion 82a, and the recessed portion 82y of the protruding portion 82b. As illustrated in FIG. 6, the protruding portion 81a of the positive electrode terminal 81 and the protruding portion 82a of the negative electrode terminal 82 are separated by a creepage distance L13. The creepage distance L13 is a total value of a horizontal distance between a side surface of a portion of the protruding portion 81a without the recessed portion 81x and a side surface of a portion of the protruding portion 82a without the recessed portion 82x, a distance r1 being a radius of a semicircle made by the recessed portion 81x of the protruding portion 81a, a distance r2 being a radius of a semicircle made by the recessed portion 82x of the protruding portion 82a, and the thickness of the insulating sheet 83. The protruding portion 81b of the positive electrode terminal 81 and the protruding portion 82b of the negative electrode terminal 82 are separated by a creepage distance L14. The creepage distance L14 is a total value of a horizontal distance between a side surface of a portion of the protruding portion 81b without the recessed portion 81y and a side surface of a portion of the protruding portion 82b without the recessed portion 82y, a distance r1 being a radius of a semicircle made by the recessed portion 81y of the protruding portion 81b, a distance r2 being a radius of a semicircle made by the recessed portion 82y of the protruding portion 82b, and the thickness of the insulating sheet 83. The distances r1 and r2 are, for example, approximately from 0.5 mm to 2 mm, but not limited thereto.

The creepage distances L11 to L14 are set to an equal value to each other, and which value denotes a shortest distance of a route along a surface of the insulating sheet 83 between the positive and negative electrode terminals 81 and 82. The creepage distances L11 to L14 are, for example, approximately from 2 mm to 15 mm, but can be adjustable as appropriate according to breakdown voltage value of the semiconductor device according the first embodiment. For example, the creepage distances L11 to L14 may be from 3 mm to 14.5 mm. Alternatively, the creepage distances L11 to L14 may be from 6 mm to 12.5 mm. Furthermore, for the distance, a tolerance of 0.5 mm may be added to 7.5 mm when the breakdown voltage value is 750 V, and a tolerance of 0.5 mm may be added to 12 mm when it is 1200 V. Note that the creepage distances L11 to L14 do not have to be equal to each other. For example, the creepage distances L11 and L12 may be set to a shortest distance, and the creepage distances L13 and L14 may be set longer than the creepage distances L11 and L12.

FIG. 7 illustrates an equivalent circuit of the semiconductor device according to the first embodiment. As illustrated in FIG. 7, the semiconductor device according to the first embodiment constitutes a part of a three-phase bridge circuit. A drain electrode of a transistor T1 on an upper arm side is connected to a positive electrode terminal P, and a source electrode of a transistor T2 on a lower arm side is connected to a negative electrode terminal N. A source electrode of the transistor T1 and a drain electrode of the transistor T2 are connected to an output terminal U and an auxiliary source terminal S1. An auxiliary source terminal S2 is connected to the source electrode of the transistor T2. Gate control terminals G1 and G2 are connected to gate electrodes of the transistors T1 and T2. The transistors T1 and T2 contain body diodes D1 and D2 as freewheeling diodes (FWDs), which are connected in anti-parallel.

The output terminal U, the positive electrode terminal P, and the negative electrode terminal N illustrated in FIG. 7 correspond to the output terminal 80, the positive electrode terminal 81, and the negative electrode terminal 82 illustrated in FIG. 1. The transistor T1 and the body diode D1 illustrated in FIG. 7 correspond to the power semiconductor elements 3a to 3f illustrated in FIG. 1. The transistor T2 and the body diode D2 illustrated in FIG. 7 correspond to the power semiconductor elements 3g to 3l illustrated in FIG. 1. The gate control terminals G1 and G2 illustrated in FIG. 7 correspond to the control terminals 7d and 7h illustrated in FIG. 1, and the auxiliary source terminals S1 and S2 illustrated in FIG. 7 correspond to the control terminals 7c and 7g illustrated in FIG. 1.

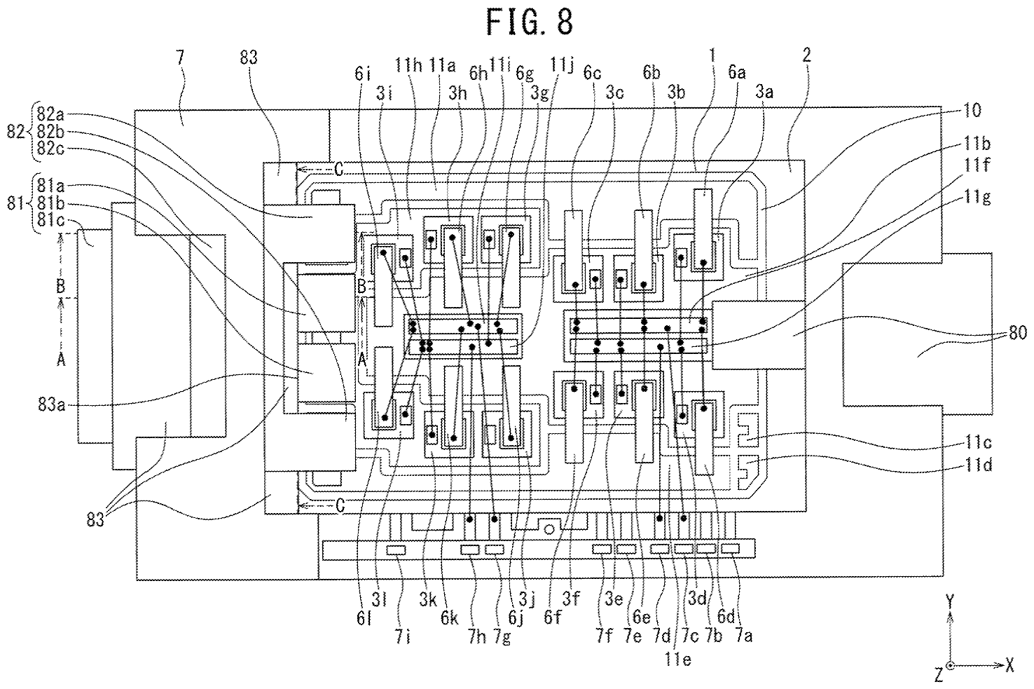

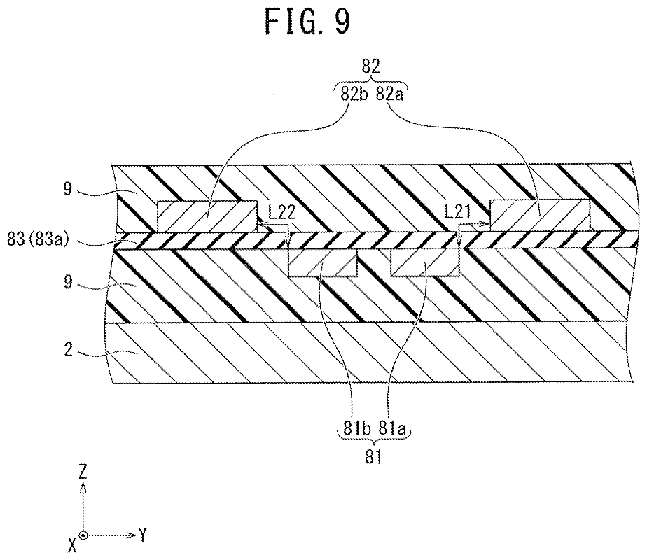

Here is a description of a semiconductor device according to a comparative example. As illustrated in FIG. 8, the semiconductor device according to the comparative example is different from the semiconductor device according to the first embodiment in that no recessed portions are provided in the protruding portions 81a and 81b of the positive electrode terminal 81 and the protruding portions 82a and 82b of the negative electrode terminal 82. FIG. 9 illustrates a section as seen from a C-C direction of FIG. 8. As illustrated in FIG. 9, the protruding portion 81a of the positive electrode terminal 81 and the protruding portion 82a of the negative electrode terminal 82 are separated by a creepage distance L21. The creepage distance L21 is a total value of a horizontal distance between a side surface of the protruding portion 81a and a side surface of the protruding portion 82a and the thickness of the insulating sheet 83. The protruding portion 81b of the positive electrode terminal 81 and the protruding portion 82b of the negative electrode terminal 82 are separated by a creepage distance L22. The creepage distance L22 is a total value of a distance between the protruding portion 81b and the protruding portion 82b and the thickness of the insulating sheet 83. In the semiconductor device according to the comparative example, when the sealing material 9 sealing the protruding portions 81a, 81b, 82a, and 82b is peeled off, the creepage distances L22 and L23 may become insufficient.

On the other hand, in the semiconductor device according to the first embodiment, the protruding portions 81a and 81b of the positive electrode terminal 81 are provided with the recessed portions 81x and 81y, and the protruding portions 82a and 82b of the negative electrode terminal 82 are provided with the recessed portions 82x and 82y. As a result, as illustrated in FIG. 6, the creepage distance L13 between the protruding portion 81a of the positive electrode terminal 81 and the protruding portion 82a of the negative electrode terminal 82 and the creepage distance L14 between the protruding portion 81b of the positive electrode terminal 81 and the protruding portion 82b of the negative electrode terminal 82, respectively, can be increased by the distances r1 of the recessed portions 81x and 81y and the distances r2 of the recessed portions 82x and 82y, allowing for improved insulation performance.

<Method for Manufacturing Semiconductor Device>

Next, an example of a method for manufacturing the semiconductor device according to the first embodiment is described with reference to FIG. 1 to FIG. 6. The lower conductive foil 12 of the insulated circuit substrate 1 illustrated in FIG. 4 and FIG. 5 is bonded to the cooling body 2 using solder, sintered material, or other bonding material. Additionally, the drain electrodes on the lower surface sides of the power semiconductor elements 3a to 3l are bonded to the upper conductive foils 11b and 11h of the insulated circuit substrate 1 illustrated in FIG. 1 using solder, sintered material, or other bonding material.

Next, the source electrodes on the upper surface sides of the power semiconductor elements 3a to 3l and the upper conductive foils 11a, 11b, and 11e are electrically connected using the lead frames 6a to 6l made of copper (Cu), aluminum (Al), or the like by solder, sintered material, or other bonding material. The electrical connection may be made using ultrasonic bonding or the like with wire, ribbon or the like. The gate electrodes on the upper surface sides of the power semiconductor elements 3a to 3l are small in current capacity, and therefore are electrically connected to the upper conductive foils 11g and 11j by wire bonding of aluminum (Al) or the like.

Then, the insulating sheet 83 is prepared and formed into a shape corresponding to the shapes of the positive and negative electrode terminals 81 and 82 using a die or the like. The positive and negative electrode terminals 81 and 82 are formed from a copper (Cu) sheet or the like by die punching. At this time, the recessed portions 81x and 81y of the protruding portions 81a and 81b of the positive electrode terminal 81 and the recessed portions 82x and 82y of the protruding portions 82a and 82b of the negative electrode terminal 82 are also formed.

Next, the insulating sheet 83 is stacked between the positive and negative electrode terminals 81 and 82, and installed in a mold. At the same time, the output terminal 80 and the control terminals 7a to 7i are installed in the mold. Then, using a resin material, the case 7 inserted with the positive electrode terminal 81, the negative electrode terminal 82, the output terminal 80, and the control terminals 7a to 7i is molded to integrate the positive and negative electrode terminals 81 and 82, the output terminal 80, and the control terminals 7a to 7i with the case 7.

Next, the case 7 insert-molded with the positive and negative electrode terminals 81 and 82, the output terminal 80, and the like is glued to the cooling body 2 so as to surround the insulated circuit substrate 1 and the power semiconductor elements 3a to 3l. The positive and negative electrode terminals 81 and 82 and the output terminal 80 are bonded to the upper conductive foils 11a, 11b, 11e, and 11h via the spacers 5a and 5b or the like. For example, solder or other bonding material may be used to bond the spacers 5a and 5b or the like to the upper conductive foils 11a, 11b, 11e, and 11h, and laser welding may be used to bond the spacers 5a and 5b or the like to the positive and negative electrode terminals 81 and 82 and the output terminal 80. The control terminals 7c, 7d, 7g, and 7h and the upper conductive foils 11f, 11g, 11i, and 11j are electrically connected by wire bonding or the like.

Then, the range surrounded by the cooling body 2 and the case 7 is sealed by the sealing material 9 such as sealing resin so that the insulated circuit substrate 1 and the power semiconductor elements 3a to 3l are protected. This completes the semiconductor device according to the first embodiment.

### Second Embodiment

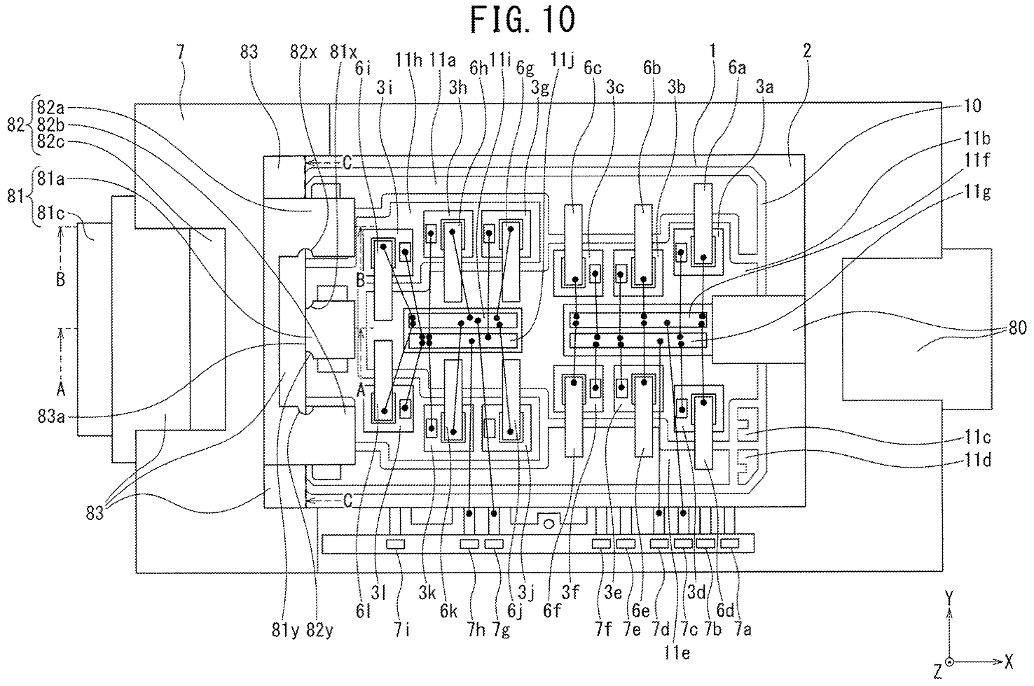

A semiconductor device according to a second embodiment is different from the semiconductor device according to the first embodiment in that the positive electrode terminal 81 includes a single protruding portion 81a, as illustrated in FIG. 10. The width and thickness of the single protruding portion 81a can be adjusted as appropriate according to the current capacity of the power semiconductor elements 3a to 3l. Additionally, in the semiconductor device according to the second embodiment, the end portion 83a of the insulating sheet 83 is extended further inward into the case 7 than in the semiconductor device according to the first embodiment.

The recessed portions 81x and 81y are provided at positions of the protruding portion 81a intersecting the end portion 83a of the insulating sheet 83. The recessed portion 81x has a shape such that a side surface of the protruding portion 81a facing the protruding portion 82a is concaved in a direction away from the protruding portion 82a. The recessed portion 81y has a shape such that a side surface of the protruding portion 81a facing the protruding portion 82b is concaved in a direction away from the protruding portion 82b.

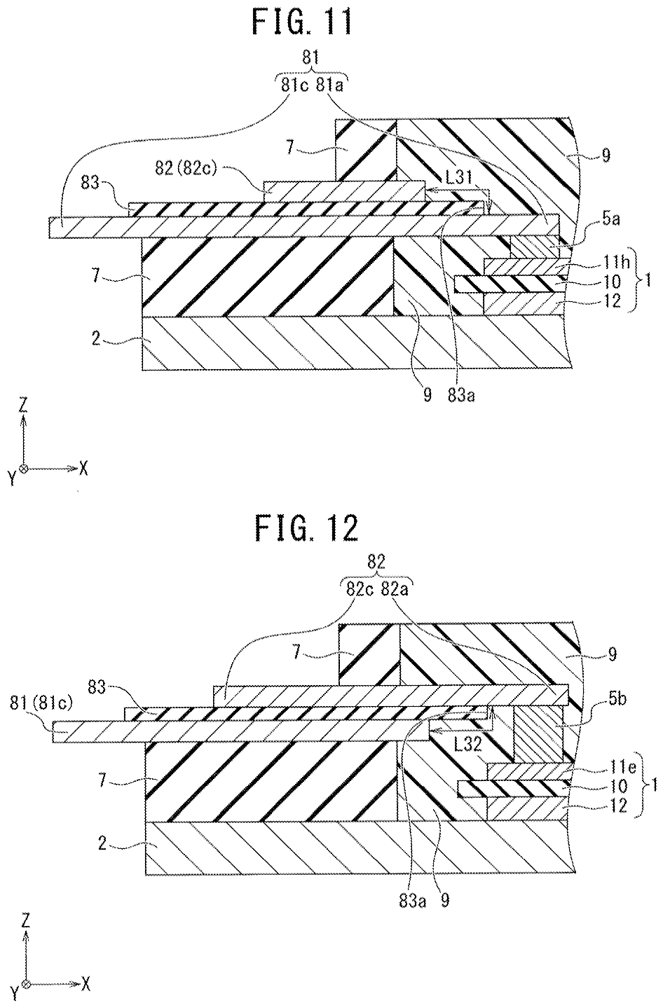

FIG. 11 illustrates a section as seen from an A-A direction passing through the protruding portion 81a of the positive electrode terminal 81 of FIG. 10. As illustrated in FIG. 11, the protruding portion 81a of the positive electrode terminal 81 and the main body portion 82c of the negative electrode terminal 82 are separated by a creepage distance L31. Since the end portion 83a of the insulating sheet 83 is extended further inward into the case 7, the creepage distance L31 is longer than the creepage distance L11 in the semiconductor device according to the first embodiment.

FIG. 12 illustrates a section as seen from a B-B direction passing through the protruding portion 82a of the negative electrode terminal 82 of FIG. 10. As illustrated in FIG. 12, the main body portion 81c of the positive electrode terminal 81 and the protruding portion 82a of the negative electrode terminal 82 are separated by a creepage distance L32. Since the end portion 83a of the insulating sheet 83 is extended further inward into the case 7, the creepage distance L32 is longer than the creepage distance L12 in the semiconductor device according to the first embodiment.

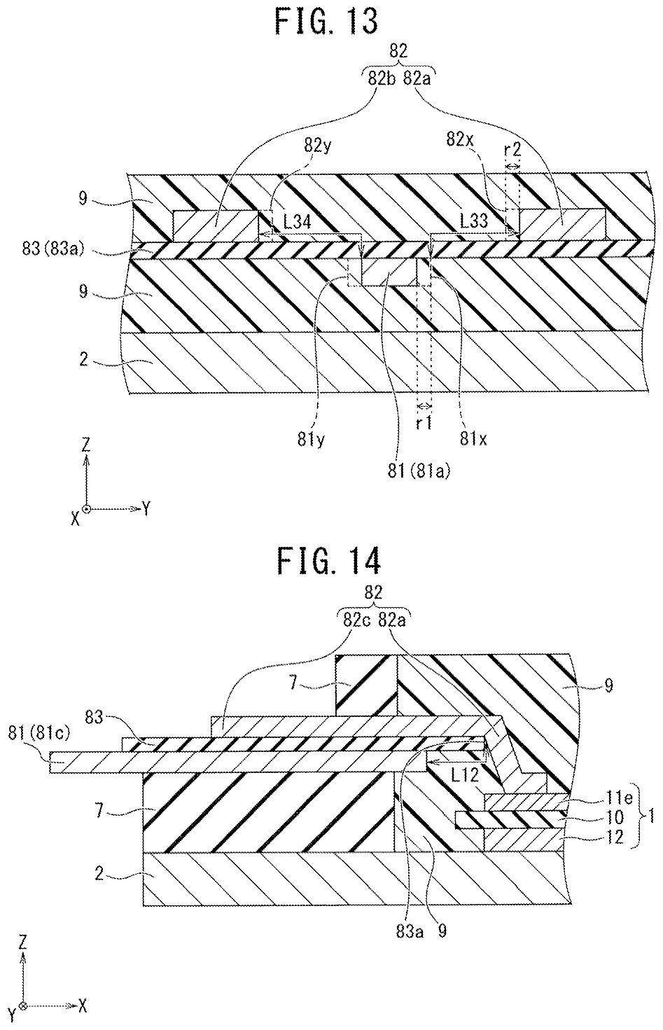

FIG. 13 illustrates a section as seen from an A-A direction passing through the recessed portions 81x and 81y of the protruding portion 81a of FIG. 10, the recessed portion 82x of the protruding portion 82a, and the recessed portion 82y of the protruding portion 82b. As illustrated in FIG. 13, the protruding portion 81a of the positive electrode terminal 81 and the protruding portion 82a of the negative electrode terminal 82 are separated by a creepage distance L33. The creepage distance L33 is a total value of a horizontal distance between a side surface of a portion of the protruding portion 81a without the recessed portion 81x and a side surface of a portion of the protruding portion 82a without the recessed portion 82x, a radius r1 of a semicircle made by the recessed portion 81x of the protruding portion 81a, a radius r2 of a semicircle made by the recessed portion 82x of the protruding portion 82a, and the thickness of the insulating sheet 83. The protruding portion 81a of the positive electrode terminal 81 and the protruding portion 82b of the negative electrode terminal 82 are separated by a creepage distance L34. The creepage distance L34 is a total value of a horizontal distance between a side surface of a portion of the protruding portion 81a without the recessed portion 81y and a side surface of a portion of the protruding portion 82b without the recessed portion 82y, a radius r1 of a semicircle made by the recessed portion 81y of the protruding portion 81a, a radius r2 of a semicircle made by the recessed portion 82y of the protruding portion 82b, and the thickness of the insulating sheet 83. Since the single protruding portion 81 is provided, the creepage distances L33 and L34 are longer than the creepage distances L13 and L14 in the semiconductor device according to the first embodiment.

For example, the creepage distances L33 and L34 are set larger than the creepage distances L31 and L32. Alternatively, the creepage distances L31, L32, L33, and L34 may be set to an equal value to each other. The other configurations of the semiconductor device according to the second embodiment are substantially the same as those of the semiconductor device according to the first embodiment, and therefore duplicate descriptions are omitted.

The semiconductor device according to the second embodiment achieves the same effects as those of the semiconductor device according to the first embodiment. Additionally, in the semiconductor device according to the second embodiment, since the positive electrode terminal 81 is provided with the single protruding portion 81a, the creepage distances L33 and L34 can be increased compared with the semiconductor device according to the first embodiment. Thus, by extending the insulating sheet 83 inward into the case 7 along with the increased creepage distances L33 and L34, the creepage distances L31 and L32 can also be increased.

### Third Embodiment

A semiconductor device according to a third embodiment is different from the semiconductor device according to the first embodiment in that the protruding portion 82a of the negative electrode terminal 82 is bent into an N-shape or a Z-shape and directly bonded to the upper conductive foil 11e via no spacer, as illustrated in FIG. 14. The protruding portion 82a is bent downward starting from the position of the recessed portion 82x at the end portion 83a of the insulating sheet 83 illustrated in FIG. 1.

The protruding portion 82a is bonded to the upper conductive foil 11e by, for example, ultrasonic bonding or laser welding. When performing ultrasonic bonding, forming the bonding portion of the protruding portion 82a to the upper conductive foil 11e into a shape divided like comb teeth can reduce damage to the insulated circuit substrate 1 due to the ultrasonic bonding. Additionally, when performing laser welding, making the bonding portion of the protruding portion 82a thinner in thickness than the upper conductive foil 11e can reduce damage to the insulated circuit substrate 1 due to the laser welding.

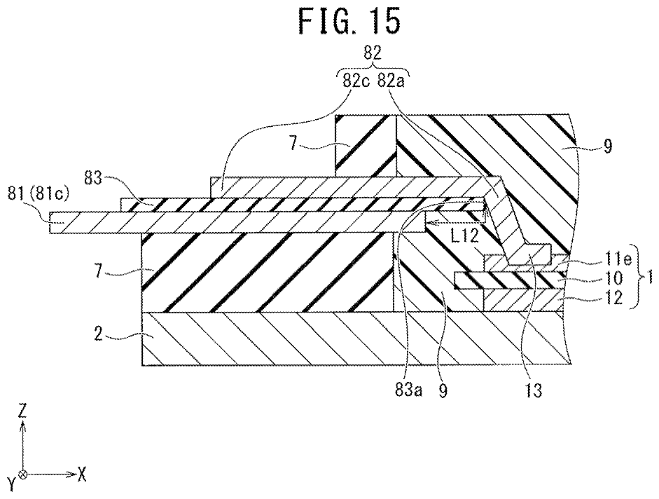

In addition, as illustrated in FIG. 15, the semiconductor device according to the third embodiment may be configured to provide a recessed portion 13 in the upper conductive foil 11e. The bonding portion of the protruding portion 82a is embedded and bonded into the recessed portion 13 of the upper conductive foil 11e. The other configurations of the semiconductor device according to the third embodiment are substantially the same as those of the semiconductor device according to the first embodiment, and therefore duplicate descriptions are omitted.

The semiconductor device according to the third embodiment achieves the same effects as those of the semiconductor device according to the first embodiment. Additionally, bending the protruding portion 82a starting from the position of the recessed portion 82x of the protruding portion 82a can facilitate bending of the protruding portion 82a. In addition, providing the recessed portion 13 in the upper conductive foil 11e allows the bonding portion of the protruding portion 82a to be easily aligned with the recessed portion 13.

### Fourth Embodiment

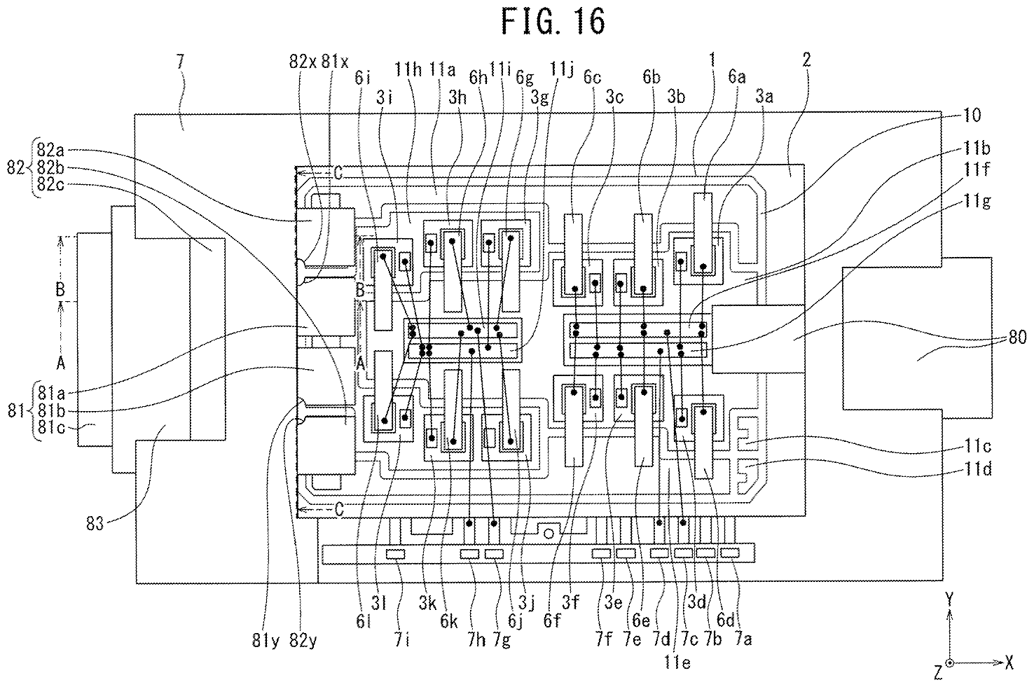

A semiconductor device according to a fourth embodiment is different from the semiconductor device according to the first embodiment in that an inner end portion of the case 7 is extended to positions of the recessed portion 81x of the protruding portion 81a, the recessed portion 81y of the protruding portion 81b, the recessed portion 82x of the protruding portion 82a, and the recessed portion 82y of the protruding portion 82b so as to cover the end portion of the insulating sheet 83, as illustrated in FIG. 16. Note that in FIG. 16, the inner end portion of the case 7 may be further extended to cover the recessed portion 81x of the protruding portion 81a, the recessed portion 81y of the protruding portion 81b, the recessed portion 82x of the protruding portion 82a, and the recessed portion 82y of the protruding portion 82b.

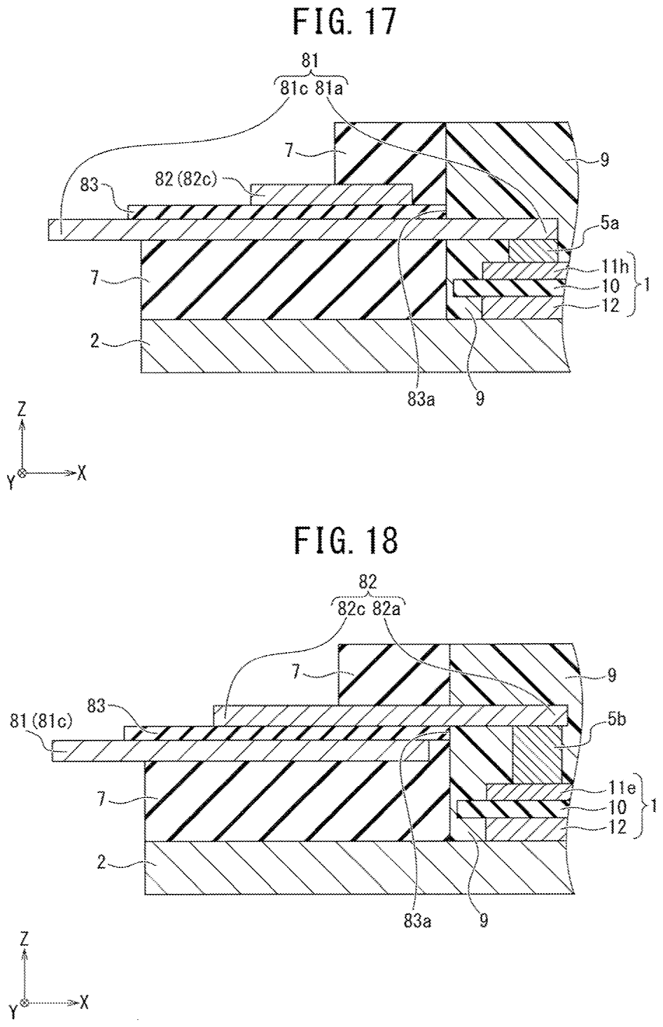

FIG. 17 illustrates a section as seen from an A-A direction of FIG. 16. As illustrated in FIG. 17, the end portion of the case 7 coincides with the end portion 83a of the insulating sheet 83 and covers an end portion of the main body portion 82c of the negative electrode terminal 82. Note that in FIG. 17, the end portion of the case 7 may be extended further inward than the end portion 83a of the insulating sheet 83 and cover the end portion 83a of the insulating sheet 83. FIG. 18 illustrates a section as seen from a B-B direction of FIG. 16. As illustrated in FIG. 18, the end portion of the case 7 coincides with the end portion 83a of the insulating sheet 83 and covers the main body portion 81c of the positive electrode terminal 81. Note that in FIG. 18, the end portion of the case 7 may be extended further inward than the end portion 83a of the insulating sheet 83 and cover the end portion 83a of the insulating sheet 83. The other configurations of the semiconductor device according to the fourth embodiment are substantially the same as those of the semiconductor device according to the first embodiment, and therefore duplicate descriptions are omitted.

The semiconductor device according to the fourth embodiment achieves the same effects as those of the semiconductor device according to the first embodiment. Additionally, the case 7 allows for insulation between the protruding portion 81a of the positive electrode terminal 81 and the main body portion 82c of the negative electrode terminal 82 and between the main body portion 81c of the positive electrode terminal 81 and the protruding portion 82a of the negative electrode terminal 82.

### Fifth Embodiment

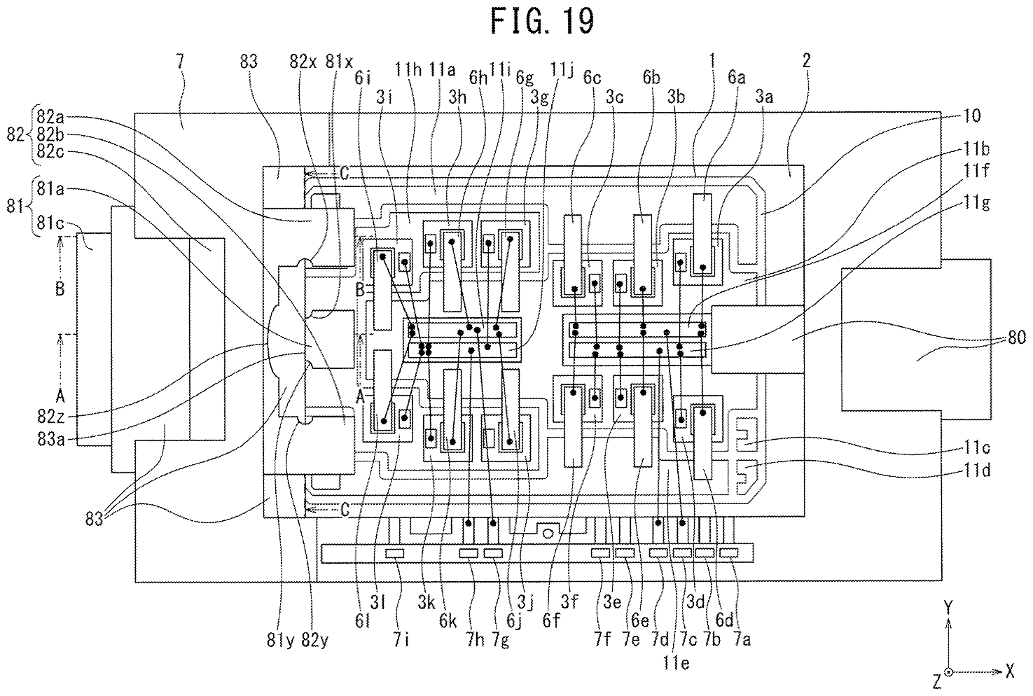

A semiconductor device according to a fifth embodiment is different from the semiconductor device according to the second embodiment in that a recessed portion 82z is provided in the main body portion 82c of the negative electrode terminal 82, as illustrated in FIG. 19. The recessed portion 82z is provided so as to concave a side surface of the main body portion 82c facing the protruding portion 81a in a direction away from the protruding portion 81a on a planar pattern.

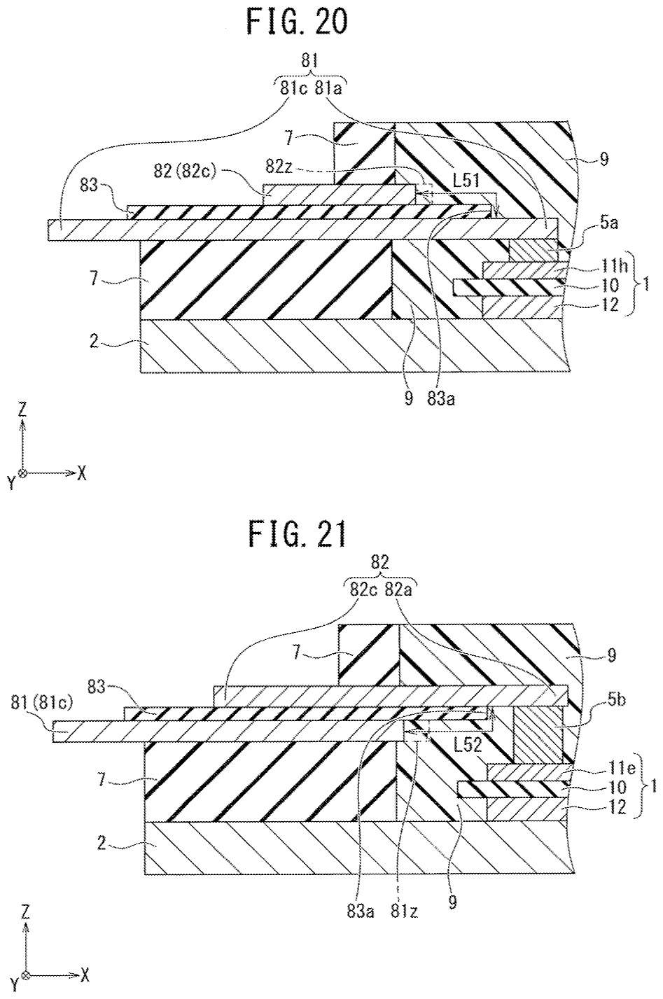

FIG. 20 illustrates a section as seen from an A-A direction of FIG. 19. As illustrated in FIG. 20, providing the recessed portion 82z in the main body portion 82c of the negative electrode terminal 82 allows a creepage distance L51 between the protruding portion 81a of the positive electrode terminal 81 and the main body portion 82c of the negative electrode terminal 82 to be longer than the creepage distance L31 in the semiconductor device according to the second embodiment.

FIG. 21 illustrates a section as seen from a B-B direction of FIG. 19. As illustrated in FIG. 21, the main body portion 81c of the positive electrode terminal 81 is also provided with a recessed portion 81z. The shape of a planar pattern of the recessed portion 81z is the same as the shape of a planar pattern of the recessed portion 82z illustrated in FIG. 19. The recessed portion 81z is provided so as to concave a side surface of the main body portion 81c facing the protruding portion 82a in a direction away from the protruding portion 82a on the planar pattern. Providing the recessed portion 81z in the main body portion 81c of the positive electrode terminal 81 allows a creepage distance L52 between the main body portion 81c of the positive electrode terminal 81 and the protruding portion 82a of the negative electrode terminal 82 to be longer than the creepage distance L32 in the semiconductor device according to the second embodiment.

A side surface of the main body portion 81c of the positive electrode terminal 81 facing the protruding portion 82b illustrated in FIG. 19 is also provided with the same recessed portion as the recessed portion 81z so as to concave in a direction away from the protruding portion 82b. The other configurations of the semiconductor device according to the fifth embodiment are substantially the same as those of the semiconductor device according to the second embodiment, and therefore duplicate descriptions are omitted.

The semiconductor device according to the fifth embodiment achieves the same effects as those of the semiconductor device according to the second embodiment. Additionally, in the semiconductor device according to the fifth embodiment, providing the recessed portion 82z in the main body portion 82c of the negative electrode terminal 82 and providing the recessed portion 81z in the main body portion 81c of the positive electrode terminal 81 allow the creepage distances L51 and L52 to be increased.

### Other Embodiments

As described above, the invention has been described according to the first to fifth embodiments, but it should not be understood that the description and drawings implementing a portion of this disclosure limit the invention. Various alternative embodiments of the present invention, examples, and operational techniques will be apparent to those skilled in the art from this disclosure.

For example, the first to fifth embodiments have exemplified the laminated wiring structure with the positive electrode terminal 81 on the lower side and the negative electrode terminal 82 on the upper side. However, a positional relationship between the positive electrode terminal 81 and the negative electrode terminal 82 may be reversed, resulting in a laminated wiring structure with the positive electrode terminal 81 on the upper side and the negative electrode terminal 82 on the lower side.

In the first embodiment, either the recessed portions 81x and 81y of the protruding portions 81a and 81b of the positive electrode terminal 81 or the recessed portions 82x and 82y of the protruding portions 82a and 82b of the negative electrode terminal 82 may be eliminated. Additionally, in the second embodiment, either the recessed portions 81x and 81y of the protruding portion 81a of the positive electrode terminal 81 or the recessed portions 82x and 82y of the protruding portions 82a and 82b of the negative electrode terminal 82 may be eliminated.

As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present Specification.

What is claimed is:

1. A semiconductor device comprising:
an insulating sheet including a first main surface and a second main surface;
a first terminal in a shape of a plate provided to face the first main surface of the insulating sheet and including a first protruding portion protruding outward from the first main surface of the insulating sheet; and
a second terminal in a shape of a plate provided to face the second main surface of the insulating sheet and including a second protruding portion protruding outward from the second main surface of the insulating sheet side by side with the first protruding portion,
wherein a first recessed portion is provided at a position of the first protruding portion intersecting an end portion of the insulating sheet by concaving a side surface of the first protruding portion facing the second protruding portion in a direction away from the second protruding portion.

2. The semiconductor device of claim 1, wherein a second recessed portion is provided at a position of the second protruding portion intersecting the end portion of the insulating sheet by concaving a side surface of the second protruding portion facing the first protruding portion in a direction away from the first protruding portion.

3. The semiconductor device of claim 1, wherein
the first terminal further includes a third protruding portion protruding outward from the first main surface of the insulating sheet side by side with the first and second protruding portions on a side opposite to a side of the second protruding portion where the first protruding portion is provided,
a third recessed portion being provided at a position of the second protruding portion intersecting the end portion of the insulating sheet by concaving a side surface of the second protruding portion facing the third protruding portion in a direction away from the third protruding portion, and
a fourth recessed portion being provided at a position of the third protruding portion intersecting the end portion of the insulating sheet by concaving a side surface of the third protruding portion facing the second protruding portion in a direction away from the second protruding portion.

4. The semiconductor device of claim 1, wherein
the first terminal further includes a third protruding portion protruding outward from the first main surface of the insulating sheet side by side with the first and second protruding portions on a side opposite to a side of the second protruding portion where the first protruding portion is provided, and
the second terminal further includes a fourth protruding portion protruding outward from the second main surface of the insulating sheet side by side with the first to third protruding portions between the second protruding portion and the third protruding portion,
a third recessed portion being provided at a position of the fourth protruding portion intersecting the end portion of the insulating sheet by concaving a side surface of the fourth protruding portion facing the third protruding portion in a direction away from the third protruding portion, and
a fourth recessed portion being provided at a position of the third protruding portion intersecting the end portion of the insulating sheet by concaving a side surface of the third protruding portion facing the fourth protruding portion in a direction away from the fourth protruding portion.

5. The semiconductor device of claim 1, wherein the first and second terminals are used as terminals with different potentials from each other.

6. The semiconductor device of claim 1, wherein
the first terminal further includes a first main body portion connected to the first protruding portion, and
the second terminal further includes a second main body portion connected to the second protruding portion,
at least a part of the first main body portion and at least a part of the second main body portion facing each other via the insulating sheet.

7. The semiconductor device of claim 6, wherein a first creepage distance along the insulating sheet between the first protruding portion and the second protruding portion at the position of the end portion of the insulating sheet is longer than a second creepage distance along the insulating sheet between the first main body portion and the second protruding portion and a third creepage distance along the insulating sheet between the second main body portion and the first protruding portion.

8. The semiconductor device of claim 6, wherein a fifth recessed portion is provided by concaving a side surface of the first main body portion facing the second protruding portion in a direction away from the second protruding portion.

9. The semiconductor device of claim 6, wherein a sixth recessed portion is provided by concaving a side surface of the second main body portion facing the first protruding portion in a direction away from the first protruding portion.

10. The semiconductor device of claim 1, further comprising:
an insulated circuit substrate;
a power semiconductor element mounted on the insulated circuit substrate;
a case configured to house the insulated circuit substrate and the power semiconductor element inside the case and installed with the first terminal, the second terminal, and the insulating sheet; and
a sealing material provided inside the case and configured to seal the insulated circuit substrate and the power semiconductor element,
wherein the first and second terminals are electrically connected to the power semiconductor element.

11. The semiconductor device of claim 10, wherein the first terminal is bonded to the insulated circuit substrate via a spacer.

12. The semiconductor device of claim 10, wherein the first terminal is bent starting from the first recessed portion and is directly bonded to the insulated circuit substrate.

13. The semiconductor device of claim 12, wherein a seventh recessed portion is provided on a main surface of the insulated circuit substrate where the first terminal is bonded, the first terminal being bonded to the seventh recessed portion.

14. The semiconductor device of claim 6, further comprising a case installed with the first terminal, the second terminal, and the insulating sheet, the case covering an end portion of the first main body portion and an end portion of the second main body portion.
